(19) United States
(12) Patent Application Publication
(10) Pub. No.: US 2009/0140316 A1
(43) Pub. Date: Jun. 4, 2009

(54) SEMICONDUCTOR MEMORY DEVICE AND METHOD OF FABRICATING THE SAME

(75) Inventors: Takashi Sugihara, Yokkaichi (JP); Minori Kajimoto, Yokkaichi (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/277,448

(22) Filed: Nov. 25, 2008

(30) Foreign Application Priority Data
Nov. 29, 2007 (JP) 2007-308990

(51) Int. Cl. H01L 21/28; H01L 29/788

(52) U.S. Cl. 257/316; 438/591; 257/E29.3; 257/E21.21

(57) ABSTRACT

A semiconductor memory device includes an insulating film formed on a semiconductor substrate, a plurality of active areas formed on the insulating film from a semiconductor layer which is formed integrally with the substrate through openings of the insulating film, the active areas being formed by being divided into a striped shape by a plurality of trenches reaching an upper surface of the insulating film, the active areas having upper surfaces and sides respectively, a first gate insulating film formed so as to cover the upper surfaces and sides of the active areas, a charge trap layer having a face located on the first gate insulating film and confronting the upper surfaces and the sides of the active areas with the first gate insulating film being interposed therebetween, a second gate insulating film formed on the charge trap layer, and a gate electrode formed on the second gate insulating film.

### CROSS-REFERENCE TO RELATED APPLICATIONS

This application is based on and claims the benefit of priority from the prior Japanese Patent Application No. 2007-308990, filed on Nov. 29, 2007, the entire contents of which are incorporated herein by reference.

### BACKGROUND OF THE INVENTION

1. Field of the Invention

The present invention relates to a semiconductor memory device provided with a memory cell structure with a finFET configuration and a method of fabricating the same.

2. Description of the Related Art

Elements composing semiconductor memory devices have rapidly been refined with recent integration of the elements. In order that the recent trend may be complied with, a memory cell structure with a finFET configuration has been proposed, instead of a currently predominant planar cell structure. When the memory cell structure with FinFETs is employed, an amount of stored electric charge can be increased and accordingly, data retention characteristics of the memory device can be improved.

For example, Se Hoon Lee, et al. disclose a semiconductor memory device employing a memory cell structure with a finFET configuration in “Improved post-cycling characteristic of FinFET NAND Flash,” IEEE Electron Devices Meeting 2006, December 2006, p. 1-4. According to the technique disclosed by Se Hoon Lee, et al., a plurality of active areas extend in parallel in a predetermined direction. SiO₂ (gate insulating film)/SiN (charge trap layer)/Al₂O₃ film (gate insulating film) are sequentially deposited so as to cover the active areas. Furthermore, TaN/polysillicon are deposited on the SiO₂/SiN/Al₂O₃ films. The deposit serves as a word line. However, although plural active areas are isolated from one another by desired element isolation regions, regions functioning as the active areas have non-uniform levels. Consequently, coupling ratios vary and accordingly, characteristics of the semiconductor memory device vary during write/delete time. As a result, there is a possibility of variations in memory cell characteristics. Additionally, a problem of current leak arises between active areas.

### BRIEF SUMMARY OF THE INVENTION

According to one aspect of the present invention, there is provided a semiconductor memory device comprising a semiconductor substrate; an insulating film formed on the semiconductor substrate and having a plurality of openings and an upper surface that is continuous; a plurality of active areas formed on the insulating film from a semiconductor layer which is formed integrally with the semiconductor substrate through the openings of the insulating film and which has an upper surface that is even, the active areas being formed by being divided into a striped shape by a plurality of trenches reaching the upper surface of the insulating film, the active areas having upper surfaces and sides respectively; a first gate insulating film formed so as to cover the upper surfaces and the sides of the active areas; a charge trap layer having a face located on the first gate insulating film and confronting the upper surfaces and the sides of the active areas with the first gate insulating film being interposed therebetween; a second gate insulating film formed on the charge trap layer; and a gate electrode formed on the second gate insulating film.

According to another aspect of the invention, there is provided a method of fabricating a semiconductor memory device, comprising forming a stacked structure including a lower semiconductor layer, an upper semiconductor layer and an insulating film located between the lower and the upper semiconductor layers, the insulating film including a plurality of openings to connect the lower and the upper semiconductor layers to each other; forming a plurality of trenches in the upper semiconductor layer to expose a first upper surface of the insulating film, thereby forming a plurality of active areas with respective side surfaces and a second upper surface; forming a first gate insulating film along the side surfaces of the respective active areas and the second upper surface of the active areas; forming a charge trap layer on the first gate insulating film; forming a second gate insulating film on the charge trap layer; and forming a gate electrode on the second)gate insulating film.

According to further another aspect of the invention, there is provided a method of fabricating a semiconductor memory device, comprising forming an insulating film on a semiconductor substrate so that the insulating film has a plurality of openings and an upper surface having a uniform level except for portions thereof corresponding to the respective openings; forming a semiconductor layer on an upper surface of the insulating film and in the openings of the insulating film so that the semiconductor layer has an even upper surface; forming a plurality of trenches in the semiconductor layer formed on the upper surface of the insulating film so that the trenches reach the upper surface of the insulating film in a region of the insulating film except for the openings, thereby forming a plurality of active areas; forming a first gate insulating film along trench-defining sides of the active areas and upper surfaces of the active areas; forming a charge trap layer on the first gate insulating film; forming a second gate insulating film on the charge trap layer; and forming a gate electrode on the second gate insulating film.

### BRIEF DESCRIPTION OF THE DRAWINGS

In the accompanying drawings:

FIG. 1 shows an electrical arrangement of a part of memory cell region of a NAND flash memory in accordance with a first embodiment of the present invention;

FIG. 2 is a schematic plan view of the part of the memory cell region;

FIGS. 3A and 3B are sectional views taken along lines 3A-3A and 3B-3B in FIG. 2 respectively;

FIGS. 4A and 4B schematically show applied voltage levels;

FIGS. 5A, 6A, 7A, 8A and 9A are schematic sectional views of the part taken along line 3A-3A in FIG. 2, showing the sections during sequential manufacturing steps;

FIGS. 5B, 6B, 7B, 8B, 9B and 10 are schematic sectional views of the part taken along line 3B-3B in FIG. 2, showing the sections during sequential manufacturing steps;

FIG. 11A is a schematic sectional view of the part taken along line 3A-3A in FIG. 2, showing the section during a manufacturing step in accordance with a second embodiment of the invention;

FIG. 11B is a schematic sectional view of the part taken along line 3A-3A in FIG. 2, showing the section during the manufacturing step in the second embodiment;

FIG. 12 is a schematic sectional view of the part taken along line 3B-3B in FIG. 2, showing the section during the manufacturing step;

FIG. 13A is a view similar to FIG. 3A;

FIG. 13B is a view similar to FIG. 3B;

FIG. 14 is a sectional view of an active area and an insulating film in a manufacturing step in a third embodiment of the invention; and

FIG. 15 is a sectional view of the active area and the insulating film in the manufacturing step in the third embodiment.

### DETAILED DESCRIPTION OF THE INVENTION

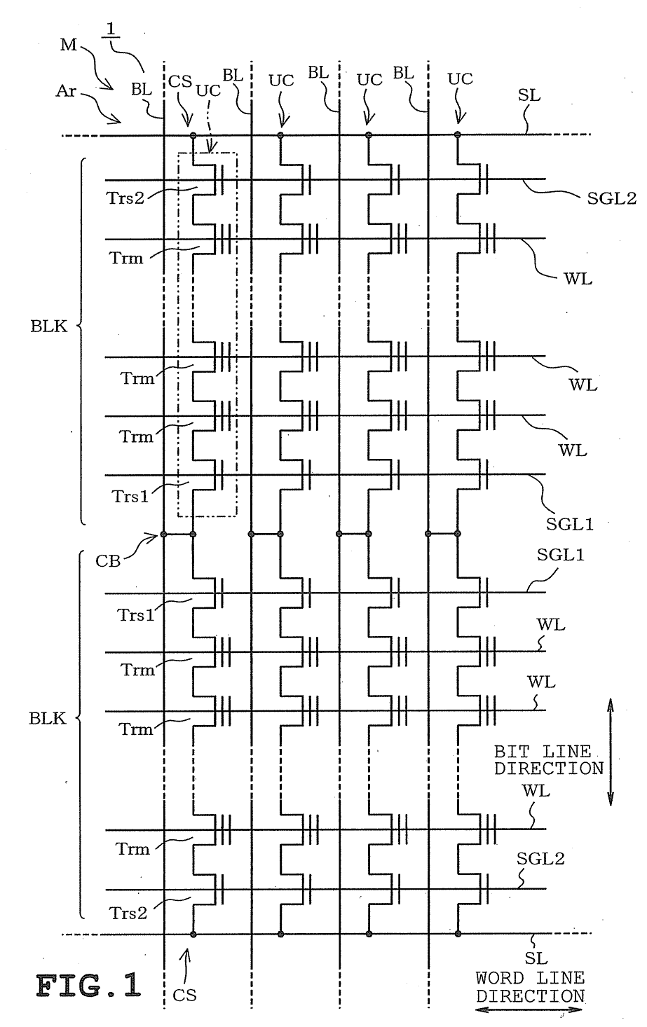

A first embodiment of the present invention will be described with reference to FIGS. 1 to 10 of the accompanying drawings. The invention is applied to a NAND flash memory in the embodiment. In the following description, identical or similar parts are labeled by the same reference numerals. The drawings typically illustrate the invention, and the relationship between a thickness and plane dimension, layer thickness ratio and the like differ from respective natural dimensions.

Referring to FIG. 1, an electrical circuit is shown that is equivalent to a part of memory cell array in a memory cell region of the NAND flash memory 1. The NAND flash memory 1 serving as a semiconductor device is divided into a memory cell region M and a peripheral circuit region (not shown). A memory cell array Ar is configured in the memory cell region M. Peripheral circuits for driving memory cells are arranged in the peripheral circuit region. The peripheral circuits are provided for reading data stored on memory cells of the memory cell array Ar in a non-volatile manner, writing data onto the memory cells and erasing data.

The memory cell array Ar in the memory cell region M includes a number of NAND cell units UC each of which includes two selective gate transistors Trs1 and Trs2, a plurality of, for example, 32 memory cell transistors Trm series-connected between the selective gate transistors Trs1 and Trs2. The NAND cell units UC are arranged in rows and columns. The memory cell transistors Trm constituting each row are arranged in the direction of word lines WL (a predetermined direction) as viewed in FIG. 1. The memory cell transistors Trm of the respective rows are connected in common to the respective word lines WL. Furthermore, the selective gate transistors Trs1 arranged in each row in the direction of word lines WL in FIG. 1 are connected in common to a selective gate line SGL1. The selective gate transistors Trs2 arranged in each row in the direction of word lines WL in FIG. 1 are connected in common to a selective gate line SGL2.

Bit line contacts CB are connected to drain regions of the selective gate transistors Trs1. The bit line contacts CB are connected to bit lines BL extending in a direction perpendicular to a direction of word line in FIG. 1 (a direction of bit line). The selective gate transistors Trs2 are connected via source line contacts CS to source lines SL extending in the direction of word line in FIG. 1.

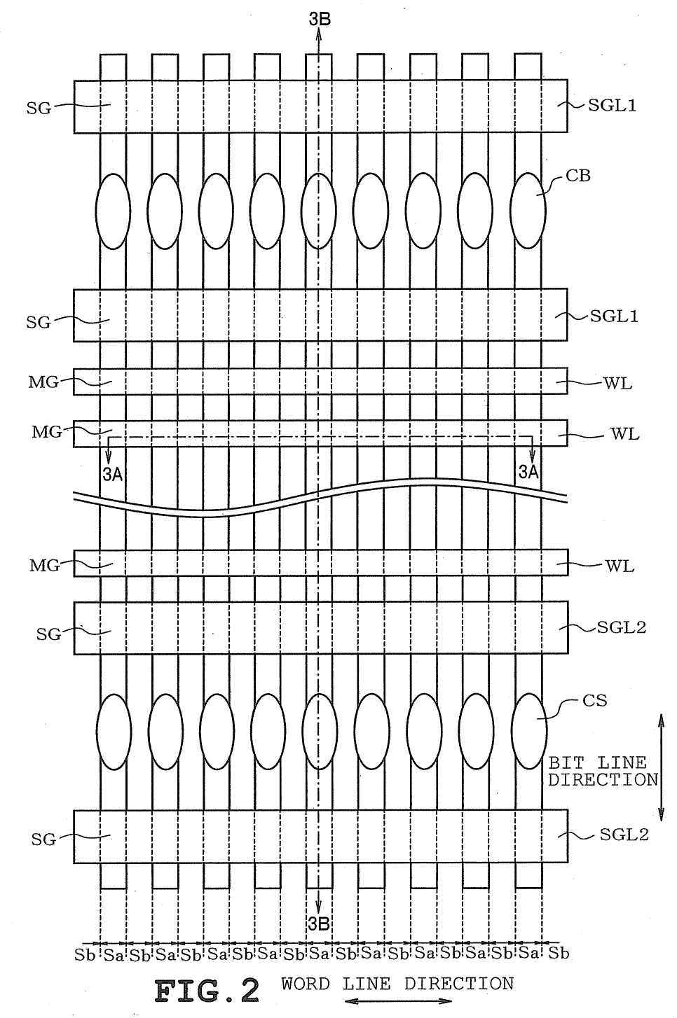

Referring now to FIG. 2, a plurality of active areas Sa are formed from a semiconductor layer so as to extend in the direction of word line at predetermined intervals. A plurality of element isolation regions Sb are also formed so as to extend in the direction of word line at predetermined intervals. The active areas Sa and the element isolation regions Sb are arranged alternately. Thus, each element isolation region Sb is located between the active areas Sa. A plurality of bit line contacts CB are formed on the active areas Sa so as to be aligned in the direction of word line respectively. A pair of selective gate lines SGL1 are formed with the bit line contacts CB being interposed therebetween as viewed in FIG. 2. The selective gate transistors Trs1 have selective gate electrodes SG formed on portions of the active areas Sa intersecting the selective gate lines SGL1 respectively. The selective gate electrodes SG are connected to one another by the selective gate lines SGL1 in the direction of word line.

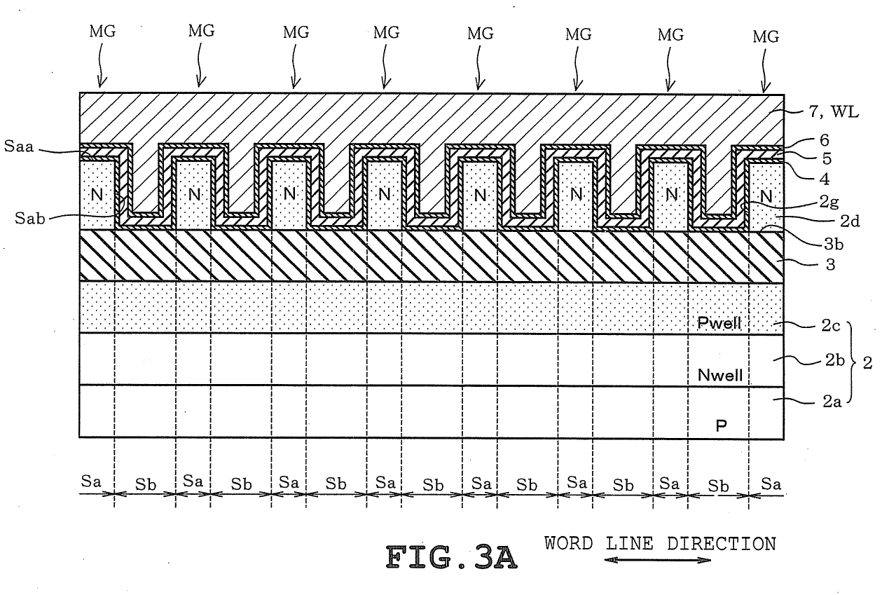

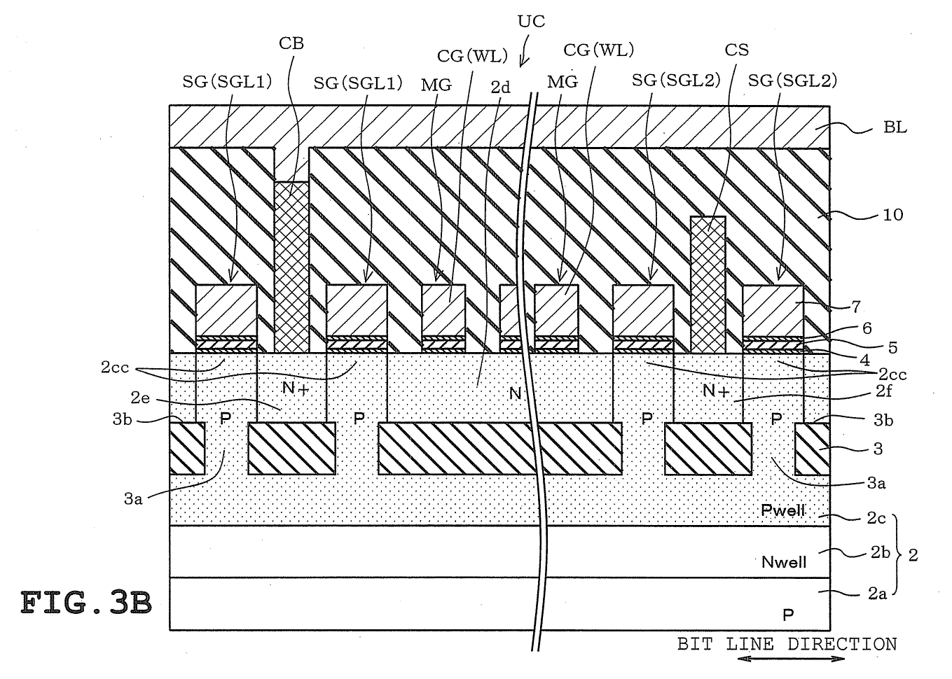

A plurality of word lines WL are formed so as to extend in a direction perpendicular to the direction in which the active areas Sa extend. The memory cell transistors Trm have gate electrodes MG formed on portions of the active areas Sa intersecting the word lines WL respectively. The gate electrodes MG are formed so as to be aligned in the directions of word line and bit line. Each word line WL is formed so as to extend over the plural active areas Sa and element isolation regions Sb and so as to connect the gate electrodes MG aligned in the direction of word line WL (see FIG. 3B about control gate electrodes CG and gate electrodes).

FIG. 3A schematically shows a section taken along line 3A-3A in FIG. 2, and FIG. 3B schematically shows a section taken along line 3B-3B in FIG. 2. A p-monocrystalline silicon substrate 2 has a surface layer in which an n-well 2b is formed as shown in FIG. 3A. A p-well 2c is further formed on the n-well 2b. The p-well 2c includes a silicon oxide film 3 composed as an insulating film (a substrate surface layer insulating film). The silicon oxide film 3 is located lower than the surface of the semiconductor substrate 2 and formed along the substrate surface to serve as an insulating film for silicon on insulator (SOI), whereby a SOI structure is configured. The silicon oxide film 3 is formed so as to be buried in the p-well 2c.

The silicon oxide film 3 is formed with openings 3a, and the p-well 2c is formed into a p-silicon layer 2cc so as to be exposed through forming regions of the openings 3a, as shown in FIG. 3B. The silicon oxide film 3 has an upper surface which is substantially flat other than the forming regions of the openings 3a as shown in FIG. 3A. The semiconductor substrate 2 has an outermost surface layer in which n-diffusion layers 2d, 2e and 2f are configured so as to be located directly on the silicon oxide film 3 as shown in FIG. 3B. The diffusion layer 2d is located on a surface layer of the p-well 2c between outer side ends of the selective gate lines SGL1 and SGL2. The diffusion layer 2e is located in a region beneath the bit line contact CB, extending from an upper surface of the silicon oxide film 3 to the surface of the silicon substrate 2. High-density n-impurities are diffused particularly in a part of the diffusion layer 2e in contact with the bit line contact CB. Accordingly, symbol “N+” is affixed to the diffusion layer 2e as shown in FIG. 3B. The diffusion layer 2f is located in a region beneath a source line contact CS, extending from the upper surface of the silicon oxide film 3 to the surface of the semiconductor substrate 2. High-density n-impurities are diffused particularly in a part of the diffusion layer 2e in contact with the bit line contact CB. Accordingly, symbol “N+” is affixed to the diffusion layer 2f. Each active area Sa as shown in FIG. 2 is constituted by the diffusion layers 2d, 2e and 2f and p-silicon layer 2cc.

An element isolation trench 2g is formed on the surface of he silicon substrate 2 as shown in FIG. 3A. The active areas Sa are formed into a stripe shape and divided in the direction of word line. In the section taken in the direction of word line as shown in FIG. 3A, the gate insulating film 4 is formed so as to cover an upper surface Saa and side walls Sab (both sides) of the plural active areas Sa. The gate insulating film 4 is formed along the upper surface Saa and sidewall surfaces Sab (both sides) of the plural active areas Sa as a tunnel insulating film. The sidewall surfaces of the active areas Sa correspond to trench forming surfaces and side surfaces.

Furthermore, the gate insulating film 4 includes a first portion formed along the sidewall surface Sab of each active area Sa and a second portion formed so as to extend from the sidewall surface Sab over the upper surface 3b of the silicon oxide film 3 continuously in the direction of word line. In the region where the cell unit UC is formed, the upper surface 3b of the silicon oxide film 3 has a substantially flat surface. In each element isolation region Sb, the gate insulating film 4 is formed directly on the upper surface of the silicon oxide film 3.

A charge trap layer 5 is formed from a silicon nitride film on the gate insulating film 4 so as to extend along upper surfaces and outer sides of the gate insulating film 4. The charge trap layer 5 has undersides and inner sides both serving as opposed faces opposed to the plural active areas Sa with the gate insulating film 4 being interposed between the charge trap layer 5 and the active areas Sa. A gate insulating film 6 is formed on the charge trap layer 5 from a deposited structure of silicon oxide films and silicon nitride films, for example, an ONO film comprising a silicon oxide film, a silicon nitride film and a silicon oxide film. The gate insulating film 6 is formed along upper surfaces and outer sides of the charge trap layer 5.

A conductive layer 7 is formed on the gate insulating film 6 as shown in FIG. 3A. The conductive layer 7 comprises polysilicon doped with impurities such as phosphor and a tungsten silicide layer formed on the polysilicon. The conductive layer 7 functions as word lines WL. In the section taken along bit line as shown in FIG. 3B, the charge trap layer 5, the gate insulating film 6 and the conductive layer 7 are sequentially deposited over the semiconductor substrate 2 with the gate insulating film 4 being interposed between the charge trap layer 5 and the silicon oxide film 3. The gate insulating film 4, the charge trap layer 5, the gate insulating film 6 and the conductive layer 7 are formed so as to have respective both sides aligned into vertical lines. Thus, each selective gate electrode SG is formed from the gate insulating films 4 and 6, the charge trap layer 5 and the conductive layer 7. Furthermore, each gate electrode MG of the memory cell is formed from the gate insulating film 4, the charge trap layer 5 and the conductive layer 7. The above-described structure of each memory cell is referred to as “finFET type.”

Furthermore, the bit line contact CB is formed directly on the diffusion layer 2e. The bit line BL is formed directly on the bit line contact CB. Each source line contact CS is formed directly on the diffusion layer 2f. An electrical connection is made between the source line contact CS and a wiring structure of the source line SL (not shown). An interlayer insulating film 10 is formed from a silicon oxide film and covers upper surfaces and sides of the source line contacts CS, the gate electrodes MG of memory cell and the selective gate electrodes SG. The interlayer insulating film 10 is further formed so as to cover the sides of the bit line contacts CB. Each memory cell transistor Trm is in an erased state when the flash memory configured as described above is in an initial state. Since a threshold voltage is negative in this case, each memory cell transistor Trm is operated in a depression mode. Furthermore, when electrons are trapped by the charge trap layer 5 of each memory cell transistor Trm, the threshold voltage is rendered positive such that each memory cell transistor Trm is operated in an enhancement mode.

The charge trap layer 5 forms such a trap level that electrons assume a metastable state. The charge trap layer 5 is externally supplied with electric field thereby to trap electrons when the electrons pass therethrough. In each memory cell, data value is determined according to a trapped state of the electrons. As a result, data is stored on each memory cell thereby to be held. The electrons are maintained in the state trapped by the charge trap layer 5 for every memory cell. Although the charge trap layer 5 is connected structurally continuously in the word line direction as described above, each memory can store data in a nonvolatile manner since the trapped state of electrons is held by each memory cell. The charge trap layer 5 is also provided in the selective gate electrode SG, whereupon electrons are trapped by the charge trap layer 5 of each selective gate electrode SG. Peripheral circuits (external circuits) apply high voltage to p-wells 2c so that the electrons trapped by the charge trap layer 5 are discharged to the p-well 2c.

Each memory cell transistor Trm has a threshold voltage that is determined according to a trapped state of electrons trapped by the charge trap layer 5. Multiple value storage techniques for storing multiple value information on a single memory have been developed with recent demands. A threshold value of each memory cell transistor Trm is controlled in a plurality of, that is, three, four or more distribution ranges. For the sake of simplification of the description, the following describes erasing, writing and reading processes in storing a binary data. In the following description, data “1” denotes an erased state in the aforesaid case and data “0” denotes the state where electrons are sufficiently trapped by the charge trap layer 5, unless otherwise noted.

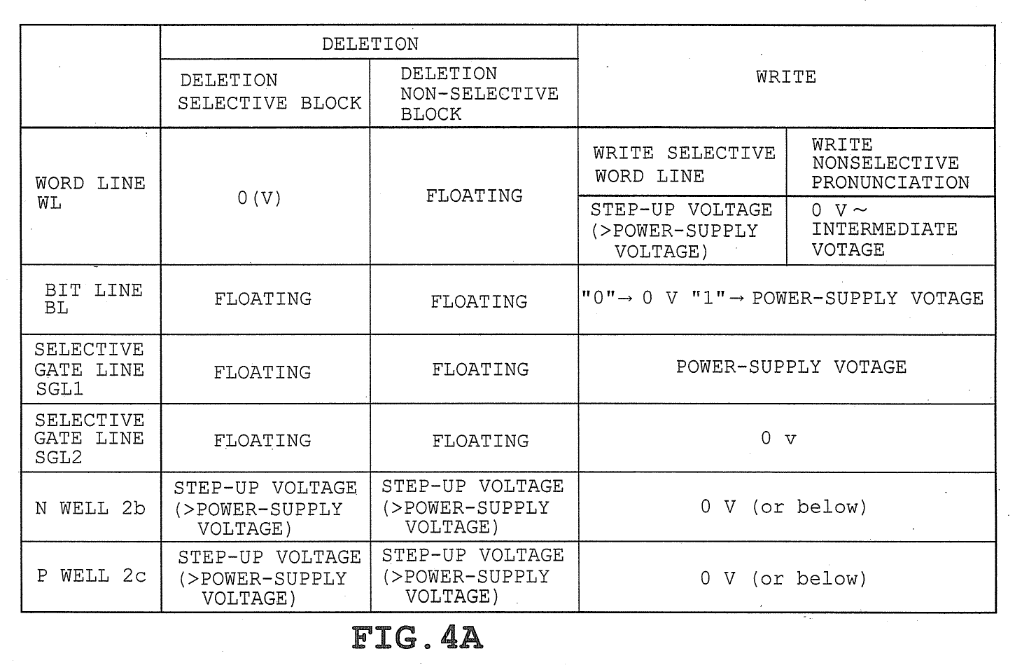

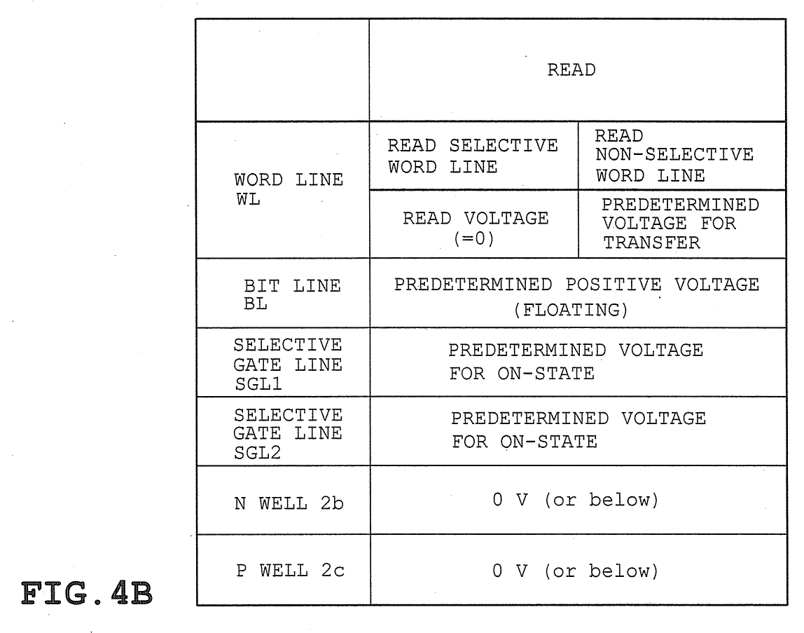

The bit lines BL, the word lines WL and selective gate lines SGL1 and SGL2 of each block BLK (see FIG. 1) are suitably biased so that the peripheral circuits of the flash memory carry out data erasing, writing and reading processes. Data erasure is carried out with plural NAND cell units UC of one block BLK arranged in the word line direction serving as a unit. FIG. 4A schematically shows levels of voltage the peripheral circuits apply in the date erasing and writing processes respectively. FIG. 4B schematically shows levels of voltage the peripheral circuits apply in the data reading process. In the erasing process, each of the selective gate lines SGL1 and SGL2, bit lines BL and source lines SL of the erase selecting block is turned into a floating state as shown in FIG. 4A, whereby 0 volts are applied to the word lines WL of the erase selecting block and positive erasing voltage (15 to 24 volts) higher than a power supply voltage to the n-well 2b and the p-well 2c. The erasing voltage is stepped up by the peripheral circuit. When erasing voltage is thus biased, the p-silicon layer 2cc and the n-diffusion layer 2d are forward biased, whereupon the potential at the n-diffusion layer 2d rises. Since the charge trap layer 5 is interposed between the word line WL and the diffusion layer 2d, electrons trapped by the charge trap layer 5 are discharged to the diffusion layer 2d, whereupon the threshold voltage of the memory cell transistor Trm is changed from the positive state to the negative state. As a result, the memory cell is changed to an erased state.

In an erasing non-selective block, the potential of the diffusion layer 2d rises simultaneously with the foregoing since the n-diffusion layer 2d is forward biased by the p-silicon layer 2cc. However, since the word line WL is turned to a floating state as shown in FIG. 4A, capacity coupling is caused between the word line WL and the diffusion layer 2d, whereupon the potential of the charge trap layer 5 rises substantially to the same level as the diffusion layer 2d. The charge trap layer 5 maintains the electrons in a trapped state. In this case, data erasing is not carried out for the memory cell.

The peripheral circuit applies voltage in the manner as shown in FIG. 4A so that data writing is carried out. More specifically, the peripheral circuit applies low voltage (0 volts or below) to the n-well 2b and p-well 2c and writing step-up voltage (high voltage, for example, 20 V) to the writing selective word line WL (a writing selective page). Furthermore, zero voltage or positive voltage lower than the writing voltage (for example, zero voltage to intermediate voltage of 10 V is applied to a writing non-selective word line WL (a writing non-selective page).

The peripheral circuit further applies positive power-supply voltage to the selective gate line SGL1 and voltage lower than the power-supply voltage to the selective gate line SGL2. Prior to the aforesaid voltage application, low voltage (0 V) is applied to the bit line BL in the case of “0” to be written, whereas the power-supply voltage is applied to the bit line BL in the case of “1” to be written. In this case, the positive potential is not applied to the diffusion layer 2d (channel region) of the memory cell for the writing of “0.” Accordingly, when the writing high voltage is applied to the word line WL, positive high voltage is applied between the writing selective word line WL and the diffusion layer 2d for “0” to be written such that an FN tunnel current flows. More specifically, electrons are trapped by the charge trap layer 5 interposed between the selected word line WL and the diffusion layer 2d for “0” to be written.

Positive bias voltage is applied to the diffusion layer 2d of the memory cell for “1” to be written. The positive bias voltage is obtained by dropping voltage applied to the bit line BL by drain-source voltage of the selected gate transistor Trs1. Electrons are not trapped by the charge trap layer 5 since similar positive bias voltage is applied to the selected word line WL. Accordingly, the erased state (data “1”) is maintained.

The peripheral circuit applies voltage in the manner as shown in FIG. 4B so that data reading is carried out. More specifically, the peripheral circuit holds the word line WL in the floating state while applying 0 voltage to the source line SL and predetermined positive voltage to the bit line BL. The peripheral circuit further applies predetermined voltage to the selective gate lines SGL1 and SGL2 so that the selective gate transistors Trs1 and Trs2 are turned to a transfer state (on-state), whereby the selective gate lines SGL1 and SGL2 function as transfer gate transistors. The peripheral circuit applies predetermined reading voltage (0 V) to the reading selected gate word line and transfer voltage to reading non-selected word lines, whereby the memory cell transistors Trm of the reading non-selected memory cells function as transfer gate transistors.

Then, when the memory cell to be read stores data “0”, the memory cell transistor Trm of the memory cell to be read is turned off such that the potential of the bit line BL is maintained. On the other hand, when the memory cell to be read stores data “1,” the memory cell transistor Trm of the memory cell to be read is turned on so that positive charge is discharged from the bit line BL through the reading non-selected memory cell transistor Trm serving as a transfer gate to the source line SL side. In this case, the peripheral circuit detects potential held in the floating state on the bit line BL is detected by a sense amplifier (not shown), whereupon data can be read out.

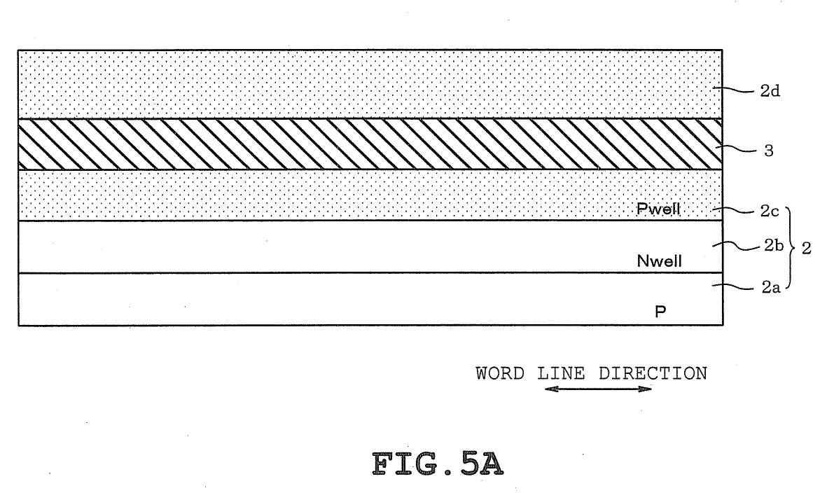

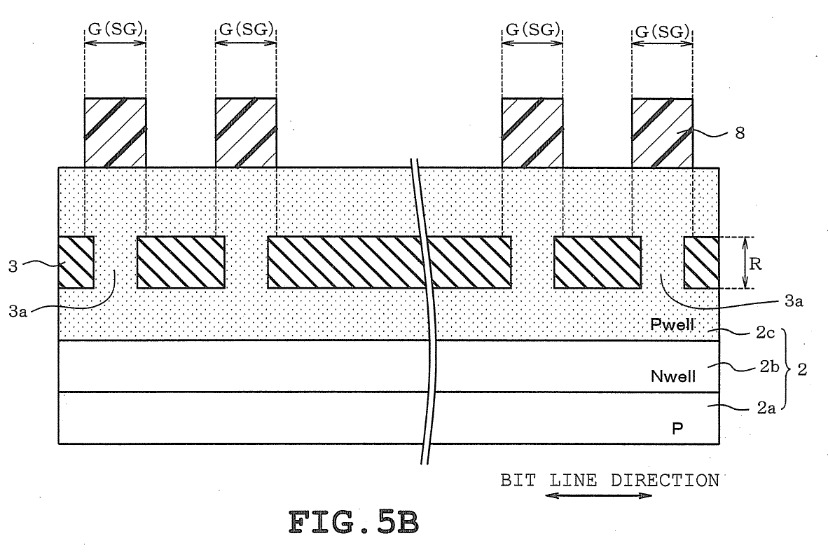

A method of fabricating the above-described arrangement will now be described. The following describes a method of fabricating a memory cell region M of the flash memory 1 with elimination of a method of fabricating the peripheral circuit. FIGS. 5A, 6A, 7A, 8A and 9A schematically show sections taken along line 3A-3A in FIG. 2 and respective fabrication steps. FIGS. 5B, 6B, 7B, 8B, 9B and 10 schematically show sections taken along line 3B-3B in FIG. 2 and respective fabrication steps.

Firstly, the n-well 2b and the p-well 2c are formed on a surface layer of the silicon substrate 2 as shown in FIGS. 5A and 5B. Subsequently, a resist 8 is applied to the silicon substrate 2 and patterned so as to conform to forming regions G of selective gate electrodes SG by a normal lithography process. Oxygen ions are implanted with the resist 8 serving as a mask, whereby a layer implanted with oxygen ions is formed so that a peak ionic concentration is reached in a region R at a predetermined depth from the surface of the silicon substrate 2.

Subsequently, annealing is carried out in a N₂-atmosphere at a predetermined temperature for a predetermined time (for example, at 1300° C. for 6 hours), so that the silicon oxide film 3 is formed in the surface layer of the silicon substrate 2 as an insulating film. Since the patterned resist 8 serves as the mask in this case, the silicon oxide film 3 is formed in the region R with the predetermined depth and has openings 3a located beneath the respective forming regions of the selective gate electrodes SG. The silicon oxide film 3 is formed so that an upper surface 3b thereof is located approximately 40 to 100 nm deep relative to the surface of the silicon substrate 2. A silicon layer 2d is formed on the silicon oxide film 3 so that an upper surface thereof is exposed. At a fabrication step as shown in FIG. 5A, the silicon layer 2d serving as an upper semiconductor layer is formed in a forming region of a diffusion layer so that an upper surface thereof is exposed. Accordingly, reference symbol “2d” is assigned to the silicon layer in FIG. 5A although used to designate the diffusion layer. Furthermore, the p-well 2c located under the silicon oxide film 3 serves as a lower semiconductor layer. The silicon oxide film 3 is thus formed in the silicon substrate 2 by a separation by implanted oxygen (SIMOX) method.

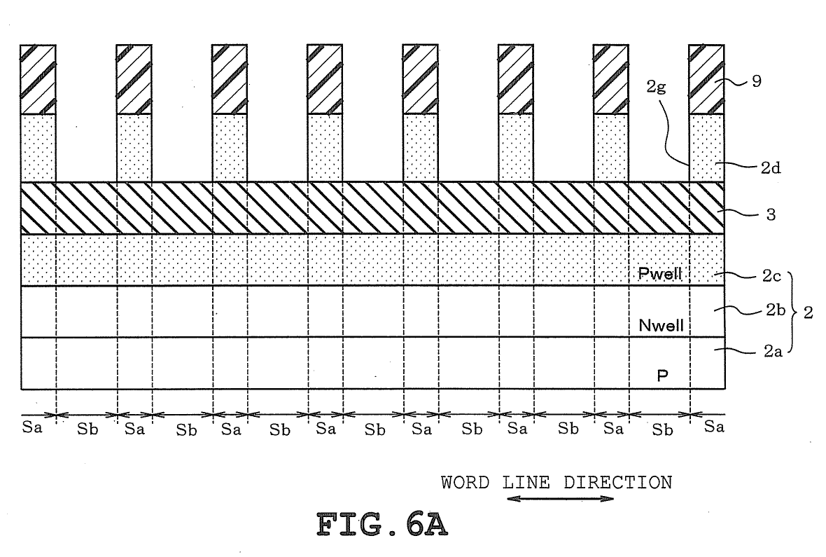

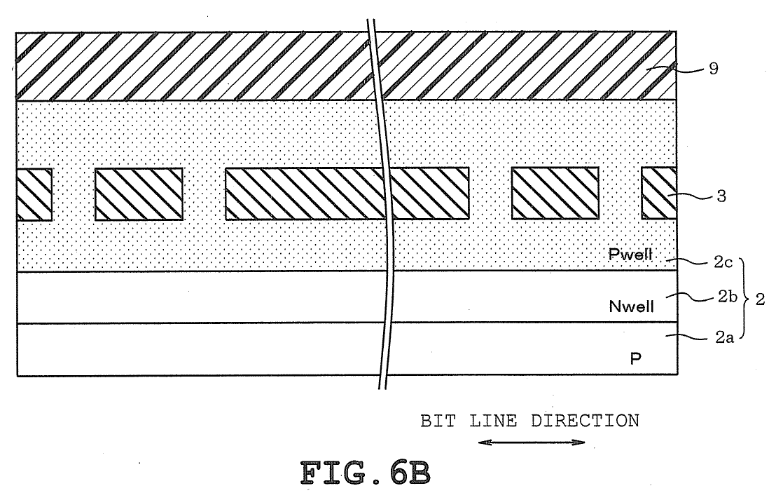

Subsequently, the resist 8 is once removed and another resist 9 is applied and patterned in a stripe shape onto the active areas Sa (a plurality of areas extending in the bit line direction and spaced away from one another in the word line direction) thereby to be formed into a mask as shown in FIGS. 6A and 6B. An anisotropic etching is carried out by a reactive ion etching (RIE) process so that the element isolation trenches 2g are formed. In this case, the silicon layer 2d is etched in the surface layer of the silicon substrate 2 under the condition that higher selectivity is given to the silicon oxide film 3. Since the silicon oxide film 3 then serves as a stopper in the etching process, the silicon layer 2d is divided by adjusting an etching time such that a plurality of active areas Sa can reliably be formed.

The silicon substrate 2 has an upper surface which is flat, and the silicon oxide film 3 also has an upper surface which is flat. Accordingly, the element isolation trenches 2a can be adjusted to have a uniform depth among the memory cells, and the active areas Sa can also be adjusted to have a uniform height among the memory cells. Furthermore, the active areas Sa are formed so as to be continuous in the bit line direction but separated in the word line direction. This configuration can suppress current leaking between the active areas Sa adjacent to each other in the word line direction. Consequently, the punch-through phenomenon can effectively be prevented, whereupon the inter-element resistance and accordingly device reliability can be improved.

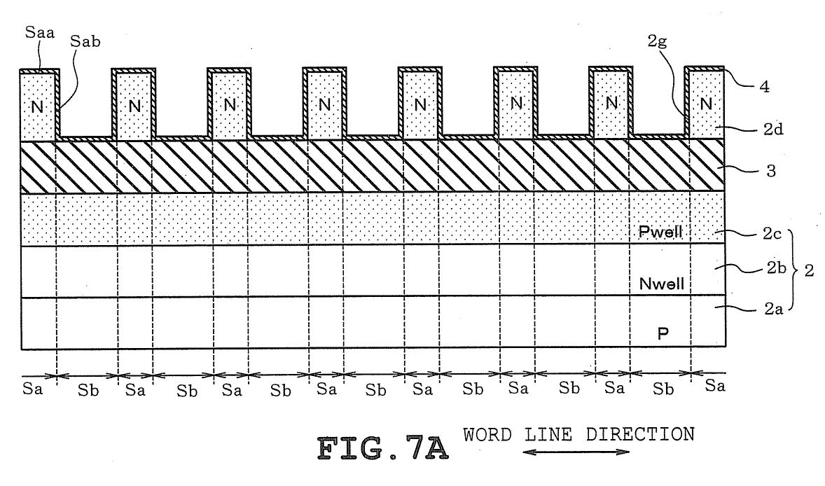

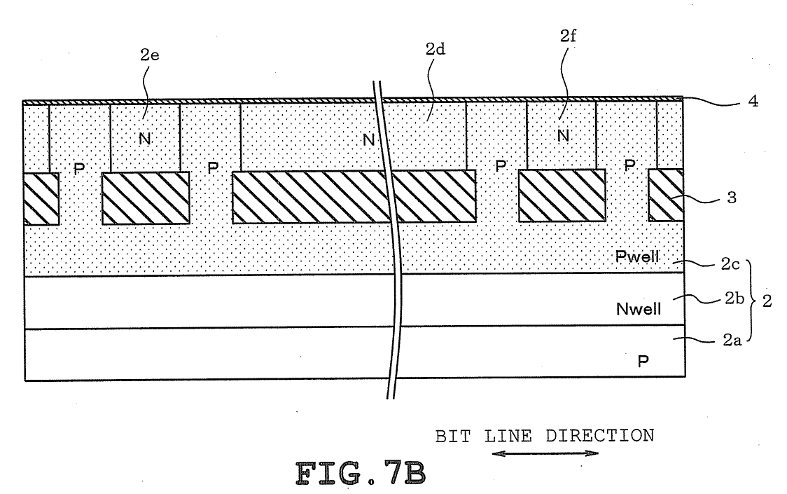

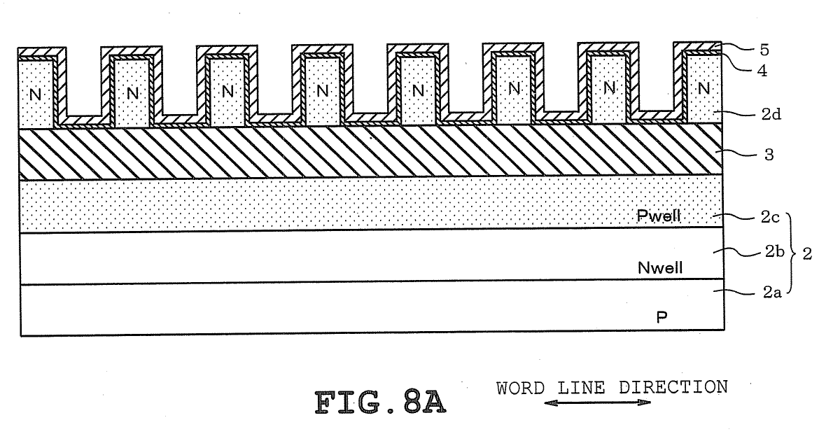

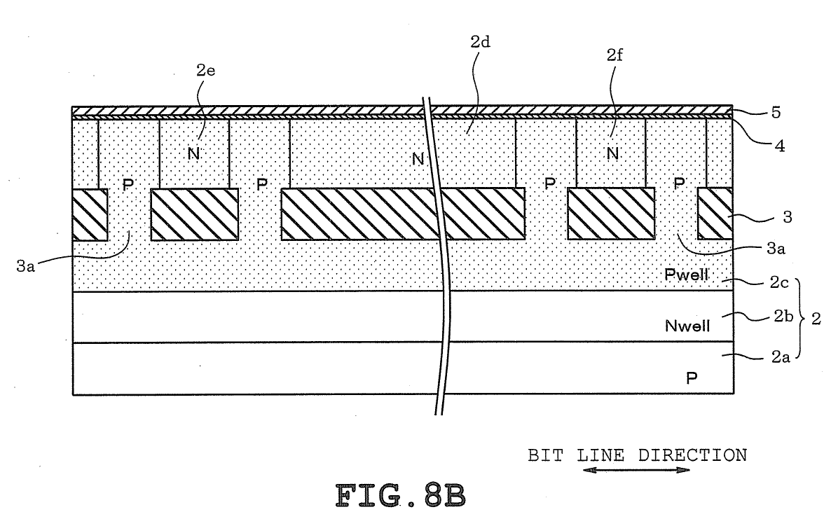

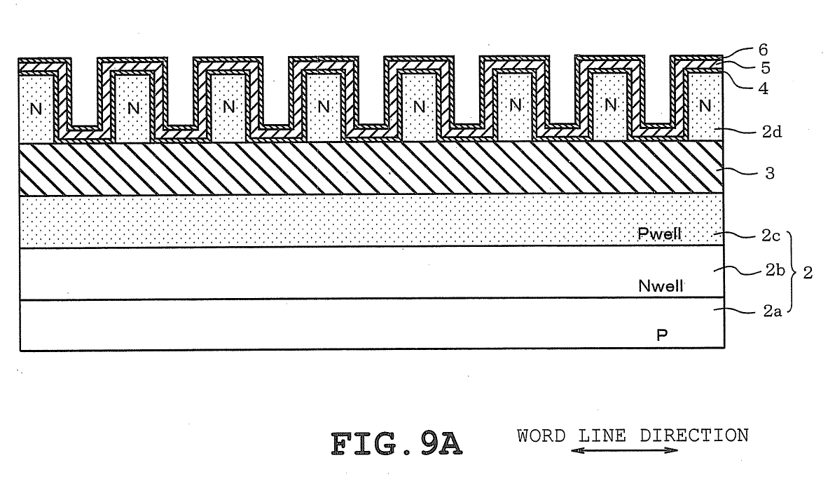

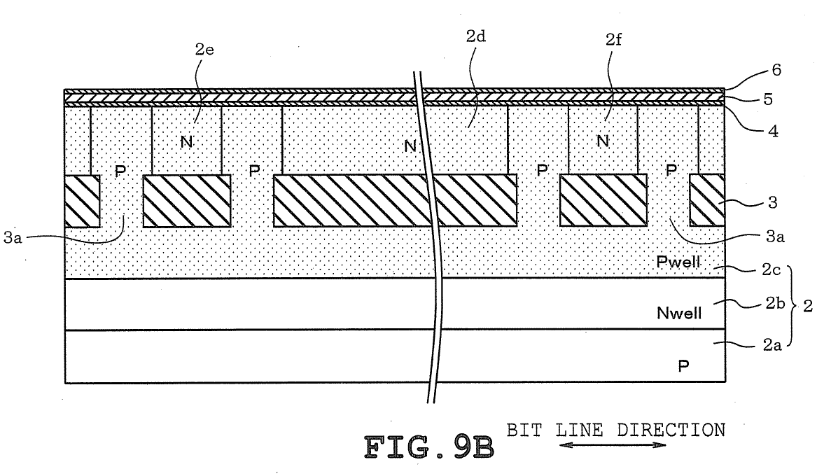

Subsequently, a resist mask for ion implantation is patterned on the active areas Sa as shown in FIGS. 7A and 7B. N-impurities such as phosphor (P), arsenic (As) and the like are implanted under a suitable condition in order that the diffusion layers 2d, 2e and 2f may be formed directly on the silicon oxide film 3. The impurities are thereafter thermally-treated thereby to be activated. Next, the resist mask is removed, and a silicon oxide film is deposited on the upper surfaces Saa and sidewalls Sab of the active areas by a chemical vapor deposition (CVD) method, serving as a gate insulating film 4. Subsequently, a silicon nitride film is deposited on upper surfaces and side surfaces of the gate insulating film 4, thereby being formed into a charge trap layer 5, as shown in FIGS. 8A and 8B. Subsequently, a silicon oxide film is formed as a gate insulating film 6 on upper surfaces and side surfaces of the charge trap layer 5 by the CVD method as shown in FIGS. 9A and 9B.

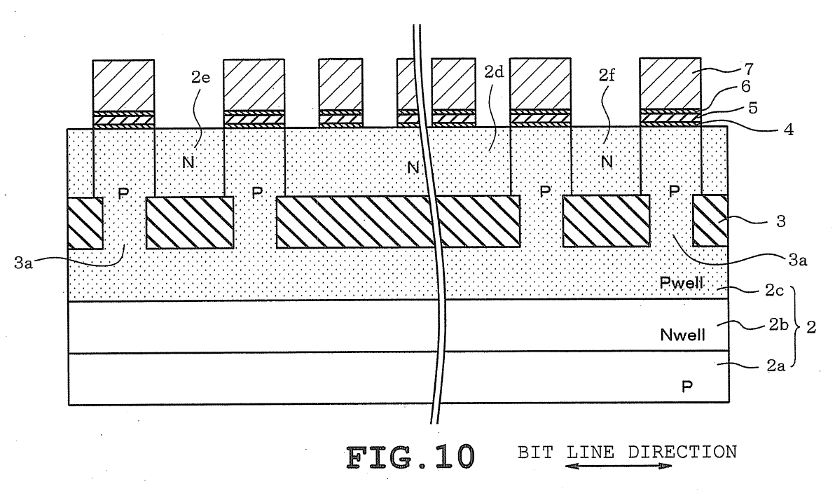

A conductive layer 7 is formed on the gate insulating film 6 as shown in FIG. 10 showing the section taken along line 3B-3B in FIG. 2. The section taken along line 3A-3A in FIG. 2 is not shown at this time since the section has the same structure as the section shown in FIG. 3A. Next, an anisotropic etching is carried out so that the conductive layer 7, gate insulating film 6, charge trap layer 5 and gate insulating film 4 are divided in the bit line direction into a plurality of portions. The interlayer insulating film 10 and the like are deposited, and contact holes are formed in the interlayer insulating film 10. Thereafter, high density diffusion layers are formed in contact regions of the silicon substrate 2 where the bit line contact CB and the source line contact CS are brought into contact with the silicon substrate 2. Multilayer wiring such as a bit line BL is further formed, whereupon the flash memory 1 is configured, although detailed description is eliminated.

According to the foregoing embodiment, the silicon substrate 2 has a flat upper surface and the silicon oxide film 3 also has a flat upper surface in the structure of the memory cell region M employing the fin structure. Accordingly, the depth of the element isolation trenches 2g can be adjusted so as to be uniform, and the active areas Sa can also be adjusted to have a uniform height among the memory cells. Consequently, an opposed region between the control gate electrode CG and the charge trap layer 5 can be adjusted so as to have a uniform area in each memory cell, whereupon a coupling ratio can be prevented from varying among the memory cells. As a result, variations in the threshold voltage can be suppressed after the writing/erasing operation of each memory cell transistor Trm, and the writing/erasing characteristic can be uniformed among the memory cells.

Furthermore, the plural active areas Sa are divided from each other by the element isolation trenches 2g each of which extends through the n-diffusion layer 2d to the flat upper surface of the silicon oxide film 3. Accordingly, each active area Sa can electrically be insulated from the adjacent active area Sa by the silicon oxide film 3, which can suppress current leaking between the active areas Sa adjacent to each other.

For example, when an element isolation technique with a shallow trench isolation (STI) structure is applied as disclosed in Japanese patent application publication, JP-A-2007-110029, there is a possibility that the depth of element isolation areas Sb may have variations due to error such as configurational difference with pattern density or the wafer in-plane position dependency. In the foregoing embodiment, however, the silicon oxide film 3 is formed by the SIMOX process, and the plural active areas Sa are divided from each other by the element isolation trenches 2g each of which extends through the n-diffusion layer 2d to the flat upper surface of the silicon oxide film 3. Consequently, the active areas Sa can reliably be divided so as to have the same height.

For example, suppose now the case where an amount of trap of the charge trap layer 5 during the writing operation is small. In this case, when electrons trapped beside the gate insulating film 4 is detrapped for some reasons, an amount of variation of a threshold per electron is apparently increased, whereupon deterioration of the data retention characteristic would be concerned. In the foregoing embodiment, however, leak current can be suppressed between the active areas Sa adjacent to each other, and the active areas Sa is adjustable so as to have the same height. This can provide an effective structure when the threshold voltage adjustment (adjustment of trapped electron amount by charge trap layer) of each memory cell transistor Trm employs multivalued memory cells.

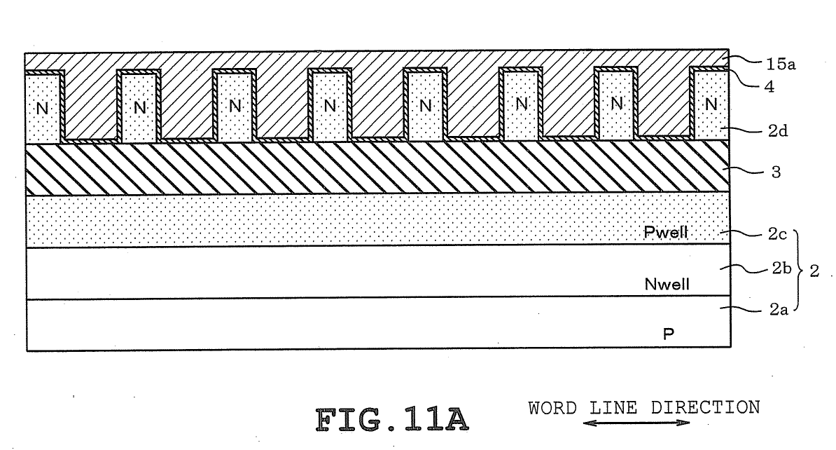

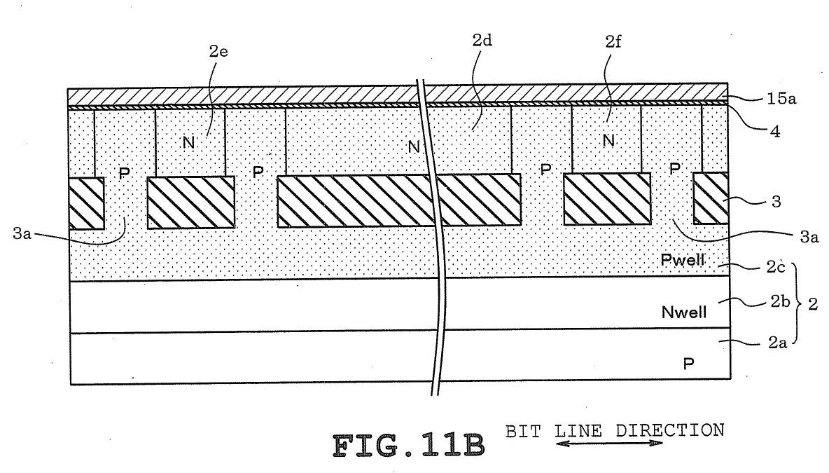

FIGS. 11A to 13B illustrate a second embodiment of the invention. The second embodiment differs from the first embodiment in the application of a charge storage layer as the charge trap layer. In the second embodiment, identical or similar parts are labeled by the same reference symbols as those in the first embodiment, and the description of these parts will be eliminated. Only the difference between the first end second embodiments will be described.

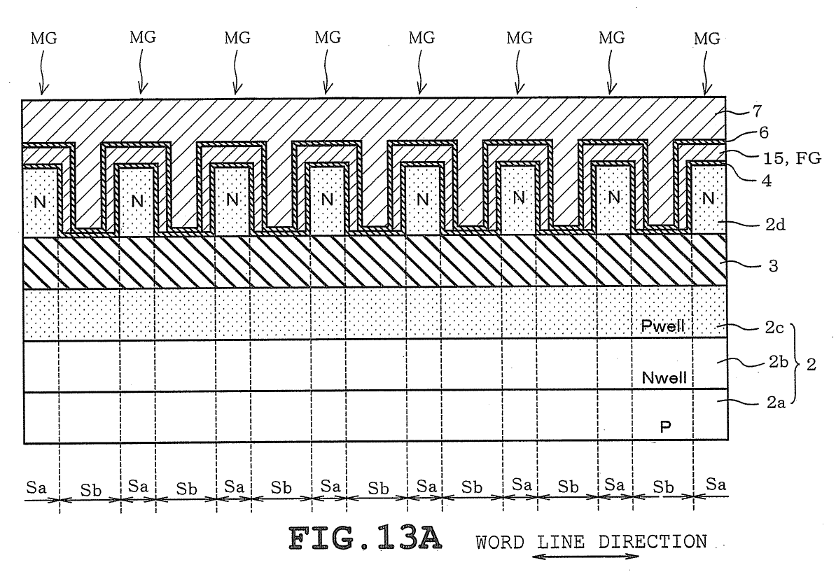

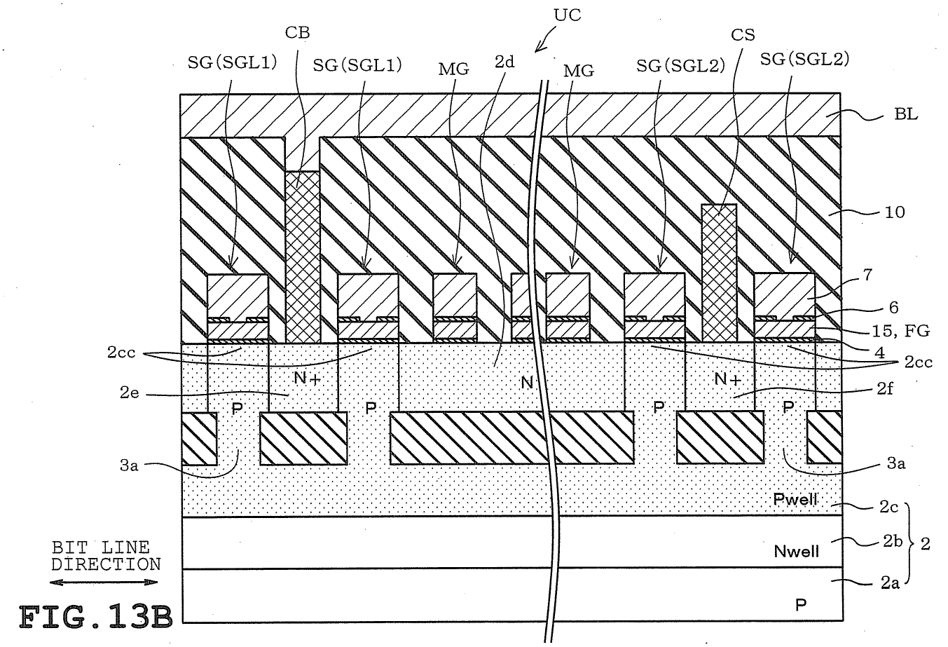

FIGS. 13A and 13B show the sections corresponding to FIGS. 3A and 3B respectively. A charge storage layer 15 is formed instead of the charge trap layer 5 employed in the first embodiment. The charge storage layer 15 is a floating gate electrode FG and differs from the charge trap layer in that the charge storage layer 15 is formed from an impurity-doped or -nondoped polysilicon. Furthermore, the charge storage layer 15 is divided in the word line direction for every memory cell as well as in the bit line direction.

The charge storage layer 15 is divided at each element isolation region Sb which is a middle region between the adjacent active areas Sa as shown in FIG. 13A. The gate insulating film 6 is formed on upper surfaces and sidewall surfaces (sides) of the charge storage layer 15. The gate insulating film 6 is formed so as to be in direct contact with another gate insulating film 4 in the middle region between the adjacent active areas Sa. The conductive layer 7 is formed so as to be structurally in contact with the upper surfaces and outer surfaces of the gate insulating film 6. Each selective gate electrode SG has substantially the same structure as each gate electrode MG as shown in FIG. 13B. Each selective gate electrode SG includes the gate insulating film 6 with a central hole via which the conductive layer 7 and the charge storage layer 15 are connected to each other structurally and electrically.

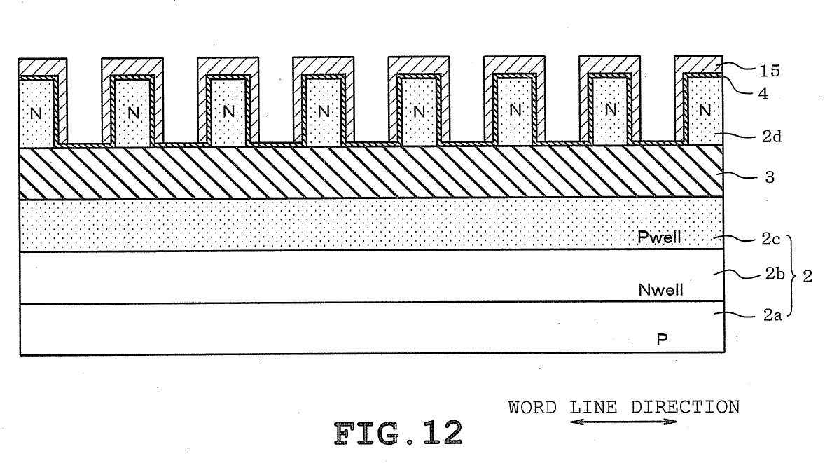

FIGS. 11A to 12 schematically illustrate the method of fabricating the above-described structure. After the gate insulating film 4 has been formed as described above in the first embodiment, polysilicon 15a is deposited on the gate insulating film 4 as shown in FIGS. 11A and 11B, and a resist (not shown) is applied to the polysilicon 15a. The resist is patterned and processed by a dry etching process such as the RIE method so that slits are formed, whereby the charge storage layer 15 is formed, as shown in FIG. 12. Subsequently, the gate insulating film 6 is deposited on the charge storage layer 15, and the conductive layer 7 is formed on the charge storage layer 15, as shown in FIGS. 13A and 13B. Since the subsequent steps are the same as those in the first embodiment, the description of the steps will be eliminated.

The second embodiment can achieve the same effect as the first embodiment even when the charge storage layer 15 is applied instead of the charge trap layer 5.

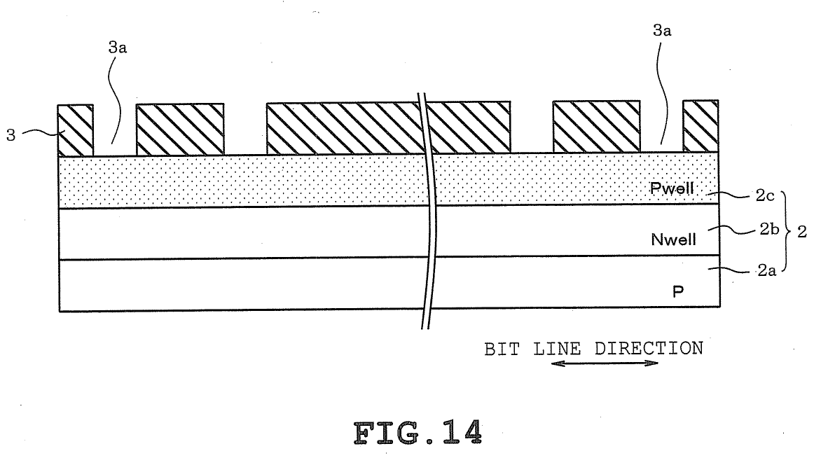

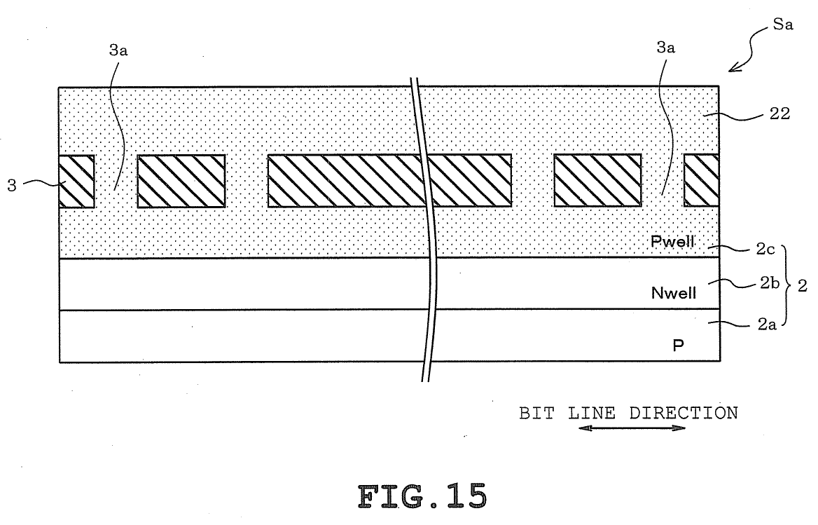

FIGS. 14 and 15 illustrate a third embodiment of the invention. The third embodiment differs from the first embodiment in that the silicon oxide film 3 and the active area Sa are formed in respective different processes from those in the first embodiment. FIGS. 14 and 15 show the respective sections in the case where the silicon oxide film 3 is formed on the silicon substrate 2. The silicon oxide film 3 with a predetermined film thickness is formed on the silicon substrate 2 by the CVD method or the like as shown in FIG. 14. Subsequently, the openings 3a are then formed in the silicon oxide film 3 by an ordinary lithography technique and the anisotropic etching.

A non-crystalline silicon 22 is subsequently deposited in the openings 3a and on the silicon oxide film 3 by the CVD method or the like as shown in FIG. 15. The non-crystalline silicon layer 22 is formed so that an upper surface thereof has a uniform level. The non-crystalline silicon layer 22 is processed mainly via the openings 3a by solid phase epitaxy (SPE), whereupon a semiconductor layer 22 constituting the active area Sa is formed. As a result, the SOI structure is obtained. Thereafter, the semiconductor layer 22 thus grown by the solid phase epitaxy is processed through the same steps as those in the first embodiment, whereby the active areas Sa are formed integrally on the semiconductor substrate 2. The third embodiment can achieve the same effect as the first embodiment.

The invention should not be limited by the foregoing embodiments. The embodiments may be modified or expanded as follows. The SOI structure and the insulating film for the SOI structure may be formed by a bonding method, instead of the method as described above. Furthermore, each control gate electrode CG (each word line WL) is formed from the conductive layer 7 with the deposited structure of polysilicon and tungsten silicide in the foregoing embodiments. However, each control gate electrode CG may be formed from a single layer of a metal or polysilicon or from a silicon compound of silicon and any metal other than tungsten, for example, cobalt, instead.

A charge trap type cell structure (namely, SONOS or MONOS structure) to which a silicon nitride film is applied may be employed as the charge trap layer 5, instead. Furthermore, although the gate insulating film 6 is formed from a silicon oxide film in the foregoing embodiments, the gate insulating film 6 may be formed from a deposited structure of a silicon oxide film and a silicon nitride film, a metal oxide, a metal compound or a deposited structure of these metal oxide and metal compound, instead.

In the first embodiment, the films 4 to 6 between the selective gate line SGL1 and the memory cell gate electrode MG are divided in the bit line direction. The films 4 to 6 between the memory cell gate electrodes MG are also divided in the bit line direction. The films 4 to 6 between the selective gate line SG and the memory sell gate electrode MG are further divided in the bit line direction. However, these may structurally be connected to one another, instead. More specifically, the films 4 to 6 may be formed on an entire memory cell region M except for the forming regions of the bit line contacts CB and source line contacts CS, instead.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor memory device comprising:
a semiconductor substrate;
an insulating film formed on the semiconductor substrate and having a plurality of openings and an upper surface that is continuous;
a plurality of active areas formed on the insulating film from a semiconductor layer which is formed integrally with the semiconductor substrate through the openings of the insulating film and which has an upper surface that is even, the active areas being formed by being divided into a striped shape by a plurality of trenches reaching the upper surface of the insulating film, the active areas having upper surfaces and sides respectively;
a first gate insulating film formed so as to cover the upper surfaces and the sides of the active areas;
a charge trap layer having a face located on the first gate insulating film and confronting the upper surfaces and the sides of the active areas with the first gate insulating film being interposed therebetween;
a second gate insulating film formed on the charge trap layer; and
a gate electrode formed on the second gate insulating film.

2. The device according to claim 1, wherein the upper surface of the insulating film has a uniform level except for portions thereof where the openings are formed respectively.

3. The device according to claim 1, wherein the charge trap layer is formed from a material containing a silicon nitride film.

4. The device according to claim 1, wherein the charge trap layer comprises a floating gate electrode.

5. The device according to claim 4, wherein the floating gate electrode comprises polysillicon.

6. The device according to claim 1, wherein the gate electrode comprises a silicon compound.

7. The device according to claim 1, wherein the gate electrode comprises a metal.

8. The device according to claim 1, wherein the second gate insulating film comprises a deposited structure of a silicon oxide film, a silicon nitride film and a metal compound.

9. The device according to claim 1, wherein the first gate insulating film, the charge trap layer, the second gate insulating film and the gate electrode constitute a multivalued memory cell.

10. A method of fabricating a semiconductor memory device, comprising:
forming a stacked structure including a lower semiconductor layer, an upper semiconductor layer and an insulating film located between the lower and the upper semiconductor layers, the insulating film including a plurality of openings to connect the lower and the upper semiconductor layers to each other;
forming a plurality of trenches in the upper semiconductor layer to expose a first upper surface of the insulating film, thereby forming a plurality of active areas with respective side surfaces and a second upper surface;
forming a first gate insulating film along the side surfaces of the respective active areas and the second upper surface of the active areas;
forming a charge trap layer on the first gate insulating film;
forming a second gate insulating film on the charge trap layer; and
forming a gate electrode on the second gate insulating film.

11. The method according to claim 10, wherein in the step of forming the insulating film, the insulating film is formed by a method of separation by implanted oxygen (SIMOX).

12. The method according to claim 11, wherein in the step of forming the insulating film, a mask is formed on a semiconductor substrate, oxygen ions are implanted in the semiconductor substrate using the mask, and a thermal treatment is carried out, whereby the insulating film with the openings is formed.

13. The method according to claim 10, wherein in each of the steps of forming the first gate insulating film, the charge trap layer, the second gate insulating film and the gate electrode, each of the first gate insulating film, the charge trap layer, the second gate insulating film and the gate electrode is formed on the upper surfaces and sides of the active areas and the upper surface of the insulating film so as to structurally extend continuously in a direction of a word line.

14. The method according to claim 13, wherein in each of the steps of forming the first gate insulating film, the charge trap layer and the second gate insulating film, each of the first gate insulating film, the charge trap layer and the second gate insulating film is formed so as to structurally extend continuously in a direction of a bit line intersecting the word line.

15. The method according to claim 14, further comprising structurally dividing the gate electrode, the second gate insulating film and the charge trap layer in the direction of the bit line while the gate electrode, the second gate insulating film, the charge trap layer and the first gate insulating film are caused to remain on the sides and the upper surfaces of the active areas and the upper surface of the insulating film continuously in the direction of the word line.

16. A method of fabricating a semiconductor memory device, comprising:
forming an insulating film on a semiconductor substrate so that the insulating film has a plurality of openings and an upper surface having a uniform level except for portions thereof corresponding to the respective openings;
forming a semiconductor layer on an upper surface of the insulating film and in the openings of the insulating film so that the semiconductor layer has an even upper surface;
forming a plurality of trenches in the semiconductor layer formed on the upper surface of the insulating film so that the trenches reach the upper surface of the insulating film in a region of the insulating film except for the openings, thereby forming a plurality of active areas;
forming a first gate insulating film along trench-defining sides of the active areas and upper surfaces of the active areas;
forming a charge trap layer on the first gate insulating film;
forming a second gate insulating film on the charge trap layer; and
forming a gate electrode on the second gate insulating film.

17. The method according to claim 16, wherein in the step of forming the charge trap layer, a charge storage layer comprising polycrystalline silicon is formed on the first gate insulating film so as to extend along sides and upper surfaces of the active areas, and thereafter, the charge storage layer is divided between the active areas while remaining in opposed regions of the sides and upper surfaces of the active areas.

18. The method according to claim 16, wherein in the semiconductor layer forming step, the semiconductor layer is formed by a solid-phase epitaxy.

19. The method according to claim 16, wherein in the insulating film forming step, the insulating film is formed by a bonding method.
